(19) United States
(12) Patent Application Publication
(10) Pub. No.: US 2025/0015735 A1
(43) Pub. Date: Jan. 9, 2025

(54) SEMICONDUCTOR DEVICE, MOTOR SYSTEM, AND VEHICLE

(71) Applicant: ROHM CO., LTD., Kyoto-shi (JP)

(72) Inventors: Kazuma SHIOMI, Kyoto-shi (JP); Yasuhito SUGIMOTO, Kyoto-shi (JP)

(21) Appl. No.: 18/894,475

(22) Filed: Sep. 24, 2024

Related U.S. Application Data
(63) Continuation of application No. PCT/JP2023/005737, filed on Feb. 17, 2023.

(30) Foreign Application Priority Data
Mar. 30, 2022 (JP) 2022-055002

(51) Int. Cl. H02P 6/14; G05F 1/46; G05F 3/24; H02P 27/04

(52) U.S. Cl. CPC H02P 6/14; G05F 1/465; G05F 3/242; H02P 27/04

(57) ABSTRACT

A semiconductor device comprises: an upper control input terminal; a lower control input terminal; a power supply terminal; a control logic unit; a reference power supply circuit configured to receive supply of the power supply voltage and to allow generation of a reference power supply voltage to be supplied to the control logic unit; and a switch circuit including switches provided for the upper control input signal and the lower control input signal respectively and switched between on and off in response to logic levels of the upper control input signal and the lower control input signal respectively. The reference power supply circuit is configured to be activated on the basis of a combination of the logic levels of the upper control input signal and the lower control input signal.

### CROSS-REFERENCE TO RELATED APPLICATIONS

This application is a continuation under 35 U.S.C. § 120 of PCT/JP2023/005737, filed Feb. 17, 2023, which is incorporated herein by reference, and which claimed priority to Japanese Application No. 2022-055002, filed Mar. 30, 2022. The present application likewise claims priority under 35 U.S.C. § 119 to Japanese Application No. 2022-055002, filed Mar. 30, 2022, the entire content of which is also incorporated herein by reference.

### TECHNICAL FIELD

The present disclosure relates to a semiconductor device.

### BACKGROUND

There is a semiconductor device conventionally known by which a half bridge is drivable that is configured by connecting an upper transistor (high-side transistor) and a lower transistor (low-side transistor) to each other. For example, such a semiconductor device includes a motor driving device that drives a three-phase brushless DC (direct-current) motor using half bridges of three phases (U-phase, V-phase, W-phase) (patent document 1, for example).

### PRIOR ART DOCUMENT

### Patent Document

Patent Document 1: Japanese Patent Application Publication No. 2014-40404

### BRIEF DESCRIPTION OF THE DRAWINGS

FIG. 1 shows the configuration of a motor system according to a comparative example;

FIG. 2 is a timing chart relating to activation of the semiconductor device according to the comparative example;

FIG. 3 shows the configuration of a motor system according to an embodiment of the present disclosure;

FIG. 4 shows exemplary specific configurations of a reference power supply circuit and a switch circuit;

FIG. 5 is a timing chart relating to activation of a semiconductor device according to the embodiment of the present disclosure;

FIG. 6 shows the configuration of a switch circuit according to a modification; and

FIG. 7 is an appearance view showing one exemplary configuration of a vehicle mounted with the motor system.

### DETAILED DESCRIPTION

An illustrative embodiment of the present disclosure will be described below by referring to the drawings.

### 1. Comparative Example

Before description of the embodiment of the present disclosure, a comparative example for comparison will be described. By doing so, a problem handled by the present disclosure will become clear.

### 1.1 Overall Configuration

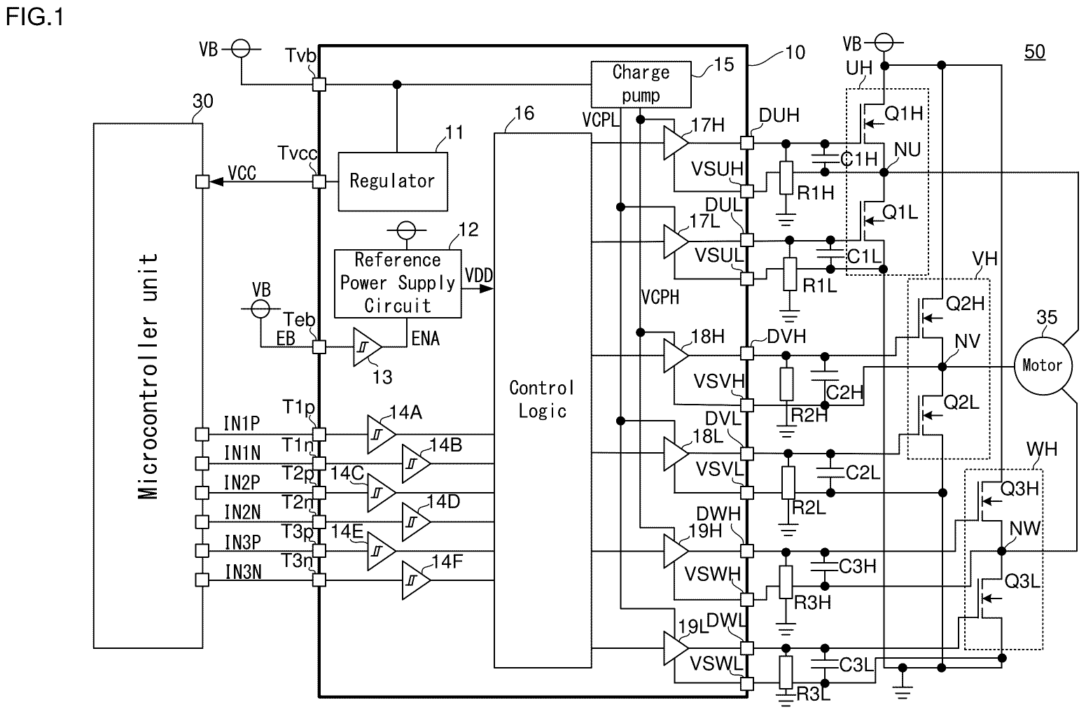

FIG. 1 shows the configuration of a motor system 50 according to the comparative example. The motor system 50 according to the comparative example shown in FIG. 1 includes a semiconductor device 10, a brushless DC motor (hereinafter simply called a motor) 35, and a microcontroller 30. The semiconductor device 10 is configured as a gate driver that drives transistors in half bridges UH, VH, and WH of three phases provided for driving the three-phase (U-phase, V-phase, W-phase) motor 35. The motor 35 is to be mounted on a vehicle.

The semiconductor device 10 includes a regulator 11, a reference power supply circuit 12, a Schmitt buffer 13, Schmitt buffers 14A to 14F, a charge pump 15, a control logic unit 16, a pre-drivers 17H and 17L, pre-drivers 18H and 18L, and pre-drivers 19H and 19L integrated into one chip, and is packaged by sealing the chip with a sealing member (resin, for example).

The semiconductor device 10 includes external terminals (pins) for establishing electrical connection to the outside, and these terminals include a power supply terminal Tvb, a regulator output terminal Tvcc, an enable terminal Teb, a U-phase upper control input terminal Tlp, a U-phase lower control input terminal Tln, a V-phase upper control input terminal T2p, a V-phase lower control input terminal T2n, a W-phase upper control input terminal T3p, a W-phase lower control input terminal T3n, a U-phase upper driving output terminal DUH, a U-phase upper source terminal VSUH, a U-phase lower driving output terminal DUL, a U-phase lower source terminal VSUL, a V-phase upper driving output terminal DVH, a V-phase upper source terminal VSVH, a V-phase lower driving output terminal DVL, a V-phase lower source terminal VSVL, a W-phase upper driving output terminal DWH, a W-phase upper source terminal VSWH, a W-phase lower driving output terminal DWL, a W-phase lower source terminal VSWL.

In addition to these external terminals shown in FIG. 1, the semiconductor device 10 includes a terminal for connection to a capacitor for charge pump, a terminal functioning both for charge pump output and for control over a power supply relay (not shown in the drawings) provided between an application terminal of a power supply voltage VB and the half bridges UH, VH, WH, a terminal for control over a motor relay transistor (not shown in the drawings) provided between the half bridges UH, VH, WH and the motor 35, a terminal for connection to an each-phase shunt resistor (a shunt resistor is not shown in FIG. 1), a terminal for outputting a voltage generated by amplifying a voltage across the each-phase shunt resistor using an amplifier to the microcontroller 30, a terminal for SPI (serial peripheral interface) communication with the microcontroller 30, and others.

### 1.2 Configuration Relating to Motor Driving

The motor system 50 includes the U-phase half bridge UH, the V-phase half bridge VH, the W-phase half bridge WH, capacitors CIH, CIL, C2H, C2L, C3H, C3L, and RIH, RIL, R2H, R2L, R3H, R3L.

The U-phase half bridge UH includes a U-phase upper transistor Q1H and a U-phase lower transistor Q1L. The U-phase upper transistor Q1H and the U-phase lower transistor Q1L are each composed of an N-channel MOSFET (metal-oxide-semiconductor field-effect transistor). A drain of the U-phase upper transistor Q1H is connected to the application terminal of the power supply voltage VB. The power supply voltage VB is a battery voltage.

A source of the U-phase upper transistor Q1H is connected to a drain of the U-phase lower transistor Q1L. A source of the U-phase lower transistor QIL is connected to an application terminal of a ground potential via a U-phase shunt resistor not shown in the drawings.

The pull-down resistor RIH is connected to a gate of the U-phase upper transistor Q1H. The capacitor CIH is connected between the gate and the source of the U-phase upper transistor Q1H. The pull-down resistor R1L is connected to a gate of the U-phase lower transistor Q1L. The capacitor C1L is connected between the gate and the source of the U-phase lower transistor Q1L.

Here, in the semiconductor device 10, the power supply terminal Tvb is connected to the application terminal of the power supply voltage VB. The charge pump 15 boosts the power supply voltage VB input to the power supply terminal Tvb, and outputs a lower boosted voltage VCPL and an upper boosted voltage VCPH. The lower boosted voltage VCPL is a first-stage output from the charge pump 15. The upper boosted voltage VCPH is a second-stage output from the charge pump 15. VCPH is larger than VCPL.

The gate of the U-phase upper transistor Q1H is connected to the U-phase upper driving output terminal DUH. An output end of the pre-driver 17H is connected to the U-phase upper driving output terminal DUH. The source of the U-phase upper transistor Q1H is connected to the U-phase upper source terminal VSUH. The pre-driver 17H is connected to an application terminal of the upper boosted voltage VCPH and the U-phase upper source terminal VSUH.

The gate of the U-phase lower transistor Q1L is connected to the U-phase lower driving output terminal DUL. An output end of the pre-driver 17L is connected to the U-phase lower driving output terminal DUL. The source of the U-phase lower transistor Q1L is connected to the U-phase lower source terminal VSUL. The pre-driver 17L is connected to an application terminal of the lower boosted voltage VCPL and the U-phase lower source terminal VSUL.

The V-phase half bridge VH includes a V-phase upper transistor Q2H and a V-phase lower transistor Q2L. The V-phase upper transistor Q2H and the V-phase lower transistor Q2L are each composed of an N-channel MOSFET. A drain of the V-phase upper transistor Q2H is connected to the application terminal of the power supply voltage VB.

A source of the V-phase upper transistor Q2H is connected to a drain of the V-phase lower transistor Q2L. A source of the V-phase lower transistor Q2L is connected to an application terminal of a ground potential via a V-phase shunt resistor not shown in the drawings.

The pull-down resistor R2H is connected to a gate of the V-phase upper transistor Q2H. The capacitor C2H is connected between the gate and the source of the V-phase upper transistor Q2H. The pull-down resistor R2L is connected to a gate of the V-phase lower transistor Q2L. The capacitor C2L is connected between the gate and the source of the V-phase lower transistor Q2L.

The gate of the V-phase upper transistor Q2H is connected to the V-phase upper driving output terminal DVH. An output end of the pre-driver 18H is connected to the V-phase upper driving output terminal DVH. The source of the V-phase upper transistor Q2H is connected to the V-phase upper source terminal VSVH. The pre-driver 18H is connected to the application terminal of the upper boosted voltage VCPH and the V-phase upper source terminal VSVH.

The gate of the V-phase lower transistor Q2L is connected to the V-phase lower driving output terminal DVL. An output end of the pre-driver 18L is connected to the V-phase lower driving output terminal DVL. The source of the V-phase lower transistor Q2L is connected to the V-phase lower source terminal VSVL. The pre-driver 18L is connected to the application terminal of the lower boosted voltage VCPL and the V-phase lower source terminal VSVL.

The W-phase half bridge WH includes a W-phase upper transistor Q3H and a W-phase lower transistor Q3L. The W-phase upper transistor Q3H and the W-phase lower transistor Q3L are each composed of an N-channel MOSFET. A drain of the W-phase upper transistor Q3H is connected to the application terminal of the power supply voltage VB.

A source of the W-phase upper transistor Q3H is connected to a drain of the W-phase lower transistor Q3L. A source of the W-phase lower transistor Q3L is connected to an application terminal of a ground potential via a W-phase shunt resistor not shown in the drawings.

The pull-down resistor R3H is connected to a gate of the W-phase upper transistor Q3H. The capacitor C3H is connected between the gate and the source of the W-phase upper transistor Q3H. The pull-down resistor R3L is connected to a gate of the W-phase lower transistor Q3L. The capacitor C3L is connected between the gate and the source of the W-phase lower transistor Q3L.

The gate of the W-phase upper transistor Q3H is connected to the W-phase upper driving output terminal DWH. An output end of the pre-driver 19H is connected to the W-phase upper driving output terminal DWH. The source of the W-phase upper transistor Q3H is connected to the W-phase upper source terminal VSWH. The pre-driver 19H is connected to the application terminal of the upper boosted voltage VCPH and the W-phase upper source terminal VSWH.

The gate of the W-phase lower transistor Q3L is connected to the W-phase lower driving output terminal DWL. An output end of the pre-driver 19L is connected to the W-phase lower driving output terminal DWL. The source of the W-phase lower transistor Q3L is connected to the W-phase lower source terminal VSWL. The pre-driver 19L is connected to the application terminal of the lower boosted voltage VCPL and the W-phase lower source terminal VSWL.

The U-phase upper transistor Q1H and the U-phase lower transistor Q1L are connected to a node NU, and the node NU is connected to a U-phase coil not shown in the drawings included in the motor 35. The V-phase upper transistor Q2H and the V-phase lower transistor Q2L are connected to a node NV, and the node NV is connected to a V-phase coil not shown in the drawings included in the motor 35. The W-phase upper transistor Q3H and the W-phase lower transistor Q3L are connected to a node NW, and the node NW is connected to a W-phase coil not shown in the drawings included in the motor 35. The coil of each phase is placed by a so-called star connection. The coil of each phase may be placed by a delta connection.

In the semiconductor device 10, the regulator 11 steps down the power supply voltage VB input to the power supply terminal Tvb to generate a power supply voltage VCC, and outputs the generated power supply voltage VCC to the microcontroller 30 from the regulator output terminal Tvcc.

A U-phase upper control input signal INIP is input from the microcontroller 30 to the U-phase upper control input terminal Tlp. The input U-phase upper control input signal INIP is input to the control logic unit 16 via the Schmitt buffer 14A. A U-phase lower control input signal ININ is input from the microcontroller 30 to the U-phase lower control input terminal Tln. The input U-phase lower control input signal ININ is input to the control logic unit 16 via the Schmitt buffer 14B.

A V-phase upper control input signal IN2P is input from the microcontroller 30 to the V-phase upper control input terminal T2p. The input V-phase upper control input signal IN2P is input to the control logic unit 16 via the Schmitt buffer 14C. A V-phase lower control input signal IN2N is input from the microcontroller 30 to the V-phase lower control input terminal T2n. The input V-phase lower control input signal IN2N is input to the control logic unit 16 via the Schmitt buffer 14D.

A W-phase upper control input signal IN3P is input from the microcontroller 30 to the W-phase upper control input terminal T3p. The input W-phase upper control input signal IN3P is input to the control logic unit 16 via the Schmitt buffer 14E. A W-phase lower control input signal IN3N is input from the microcontroller 30 to the W-phase lower control input terminal T3n. The input W-phase lower control input signal IN3N is input to the control logic unit 16 via the Schmitt buffer 14F.

Each of the control input signals IN1P to IN3N is a pulse signal having a high level and a low level. Each of the Schmitt buffers 14A to 14F performs binarization of a corresponding one of the control input signals IN1P to IN3N input thereto into a high level and low level, and outputs a resultant signal.

The control logic unit 16 drives the pre-driver 17H on the basis of the output from the Schmitt buffer 14A. This causes the pre-driver 17H to output the upper boosted voltage VCPH or a potential at the U-phase upper source terminal VSUH to the gate of the U-phase upper transistor Q1H. Then, the U-phase upper transistor Q1H is driven to be switched.

The control logic unit 16 drives the pre-driver 17L on the basis of the output from the Schmitt buffer 14B. This causes the pre-driver 17L to output the lower boosted voltage VCPL or a potential at the U-phase lower source terminal VSUL to the gate of the U-phase lower transistor Q1L. Then, the U-phase lower transistor Q1L is driven to be switched.

The control logic unit 16 drives the pre-driver 18H on the basis of the output from the Schmitt buffer 14C. This causes the pre-driver 18H to output the upper boosted voltage VCPH or a potential at the V-phase upper source terminal VSVH to the gate of the V-phase upper transistor Q2H. Then, the V-phase upper transistor Q2H is driven to be switched.

The control logic unit 16 drives the pre-driver 18L on the basis of the output from the Schmitt buffer 14D. This causes the pre-driver 18L to output the lower boosted voltage VCPL or a potential at the V-phase lower source terminal VSVL to the gate of the V-phase lower transistor Q2L. Then, the V-phase lower transistor Q2L is driven to be switched.

The control logic unit 16 drives the pre-driver 19H on the basis of the output from the Schmitt buffer 14E. This causes the pre-driver 19H to output the upper boosted voltage VCPH or a potential at the W-phase upper source terminal VSWH to the gate of the W-phase upper transistor Q3H. Then, the W-phase upper transistor Q3H is driven to be switched.

The control logic unit 16 drives the pre-driver 19L on the basis of the output from the Schmitt buffer 14F. This causes the pre-driver 19L to output the lower boosted voltage VCPL or a potential at the W-phase lower source terminal VSWL to the gate of the W-phase lower transistor Q3L. Then, the W-phase lower transistor Q3L is driven to be switched.

As described above, driving of each transistor in each of the half bridges UH, VH, and WH of the respective phases is controlled on the basis of a corresponding one of the control input signals IN1P to IN3N. By doing so, it becomes possible to control driving of the motor 35.

In each of a set of the U-phase control input signals IN1P and IN1N, a set of the V-phase control input signals IN2P and IN2N, and a set of the W-phase control input signals IN3P and IN3N, the upper control input signal and the lower control input signal are at levels complementary to each other. Specifically, if one of these signals is at a high level, the other is at a low level. If one of these signals is at a low level, the other is at a high level. By doing so, in each of the half brides UH, VH, and WH of the respective phases, the upper transistor and the lower transistor are driven complementarily. Specifically, if one of these transistors is in an on state, the other is in an off state. If one of these transistors is in an off state, the other is in an on state. Dead-time (simultaneously-off period) may be provided when both the upper transistor and the lower transistor are in an off state simultaneously. In this case, the upper control input signal and the lower control input signal are at low levels simultaneously.

The transistors in the half bridges UH, VH, and WH of the respective phases are driven in response to duties of the control input signals, thereby exerting PWM (pulse width modulation) control. This generates driving voltages at the nodes NU, NV, and NW having alternating-current waveforms shifted in phase from each other, thereby driving the motor 35.

### 1.3 Reference Power Supply Circuit

Here, in the semiconductor device 10, an enable signal EB is applicable to the enable terminal Teb from the outside. The enable signal EB is generated from the power supply voltage VB. The enable signal EB input to the enable terminal Teb is converted by the Schmitt buffer 13 to a binarized enable signal ENA having a high level and a low level. The enable signal ENA is input to the reference power supply circuit 12.

The reference power supply circuit 12 has an LDO (low drop out) as a series regulator not shown in the drawings. The power supply voltage VB is converted to a reference power supply voltage VDD by being stepped down by the LDO. The reference power supply voltage VDD is supplied as a power supply to the control logic unit 16.

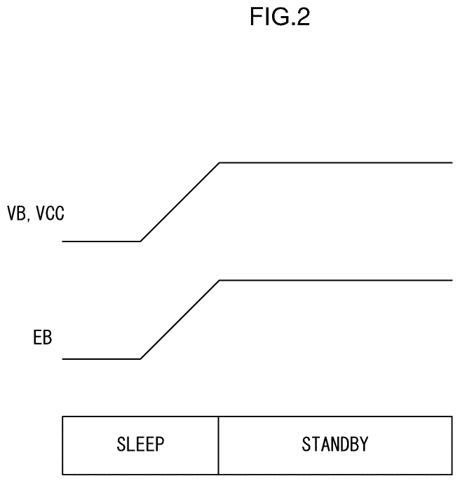

Here, activation of the semiconductor device 10 will be described by referring to the timing chart in FIG. 2. FIG. 2 shows the power supply voltages VB and VCC, the enable signal EB, and the state of the semiconductor device 10 in this order from the top.

When an ignition of a vehicle mounted with the motor system 50 is turned on, the power supply voltage (battery voltage) VB becomes on. This causes the power supply voltage VB to start to rise from 0 V, as shown in FIG. 2. This also causes the power supply voltage VCC as a power supply of the microcontroller 30 to rise.

At this time, the enable signal EB also rises. If the enable signal EB exceeds a threshold voltage for the Schmitt buffer 13, the enable signal ENA to be output from the Schmitt buffer 13 is switched from a low level to a high level. By doing so, the reference power supply circuit 12 (LDO) is activated and the reference power supply voltage VDD becomes on. Thus, the semiconductor device 10 makes a transition from a sleep state to a standby state where the control logic unit 16 is operable in response to supply of the reference power supply voltage VDD.

As described above, according to the comparative example, it is possible to activate the semiconductor device 10 using the enable signal EB. Meanwhile, the necessity for the enable terminal Teb causes a problem of an increased number of external terminals (an increased number of pins) of the semiconductor device 10. More specifically, assuming that a 48-pin package and a 64-pin package are prepared for a semiconductor device, for example, the necessity for the enable terminal Teb makes it impossible to control pins to a number equal to or less than 48, resulting in the number of pins such as 49, for example. In some cases, this inevitably requires use of a 64-pin package for the semiconductor device 10. An increased number of pins leads to size increase of the semiconductor device 10.

### 2. Embodiment of Present Disclosure

To solve the above-described problem, the embodiment of the present disclosure described below is implemented. Specifically, the embodiment of the present disclosure is intended to reduce the number of pins while maintaining the function of activating a semiconductor device.

### 2. 1 Configuration of Semiconductor Device

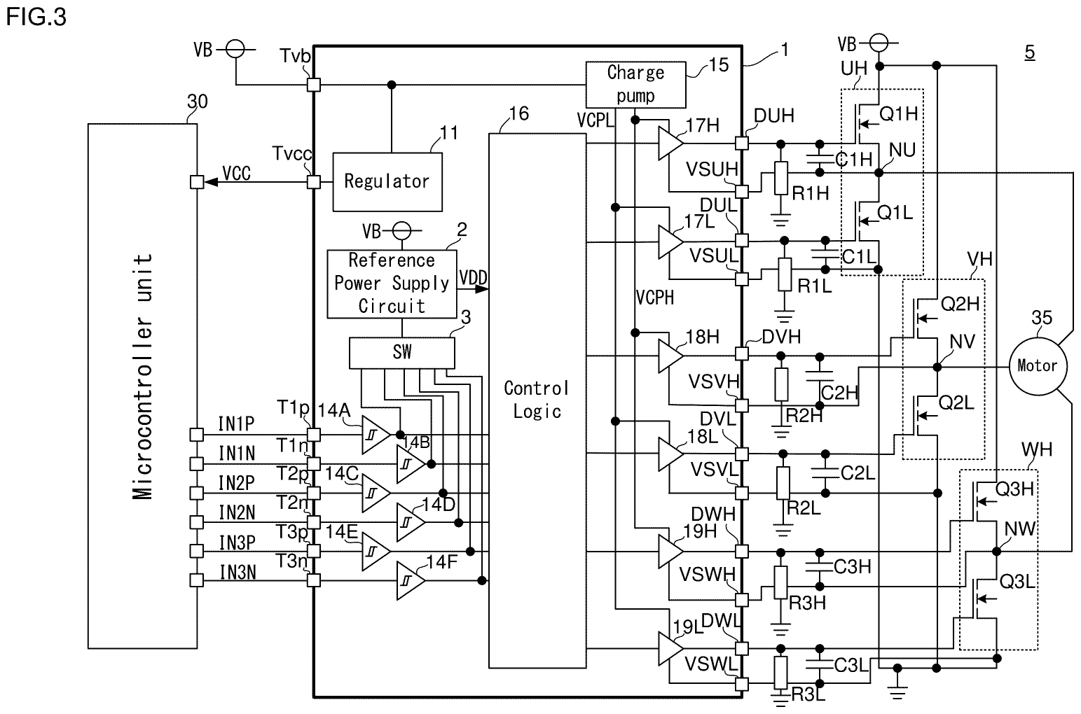

FIG. 3 shows the configuration of a motor system 5 according to the embodiment of the present disclosure. The motor system 5 shown in FIG. 3 differs from that of the comparative example (FIG. 1) described previously in that it includes a semiconductor device 1. In the motor system 5, as structures external to the semiconductor device 1 (motor 35, microcontroller 30, half bridges of respective phases, etc.) are the same as those of the comparative example, descriptions of these structures are omitted here.

As shown in FIG. 3, the semiconductor device 1 differs from the semiconductor device 10 (FIG. 1) according to the comparative example in that it includes a reference power supply circuit 2 and a switch circuit 3. In the semiconductor device 1, as structures other than the reference power supply circuit 2 and the switch circuit 3 are the same as those of the semiconductor device 10 according to the comparative example, descriptions of these structures are omitted here.

Unlike the semiconductor device 10 according to the comparative example, the semiconductor device 1 according to the embodiment of the present disclosure does not include the enable terminal Teb as an external terminal. Reason why the enable terminal Teb becomes unnecessary will be given later. As the other external terminals of the semiconductor device 1 are the same as those of the semiconductor device 10 according to the comparative example, descriptions of these external terminals are omitted here.

### 2. 2 Configuration of Reference Power Supply Circuit

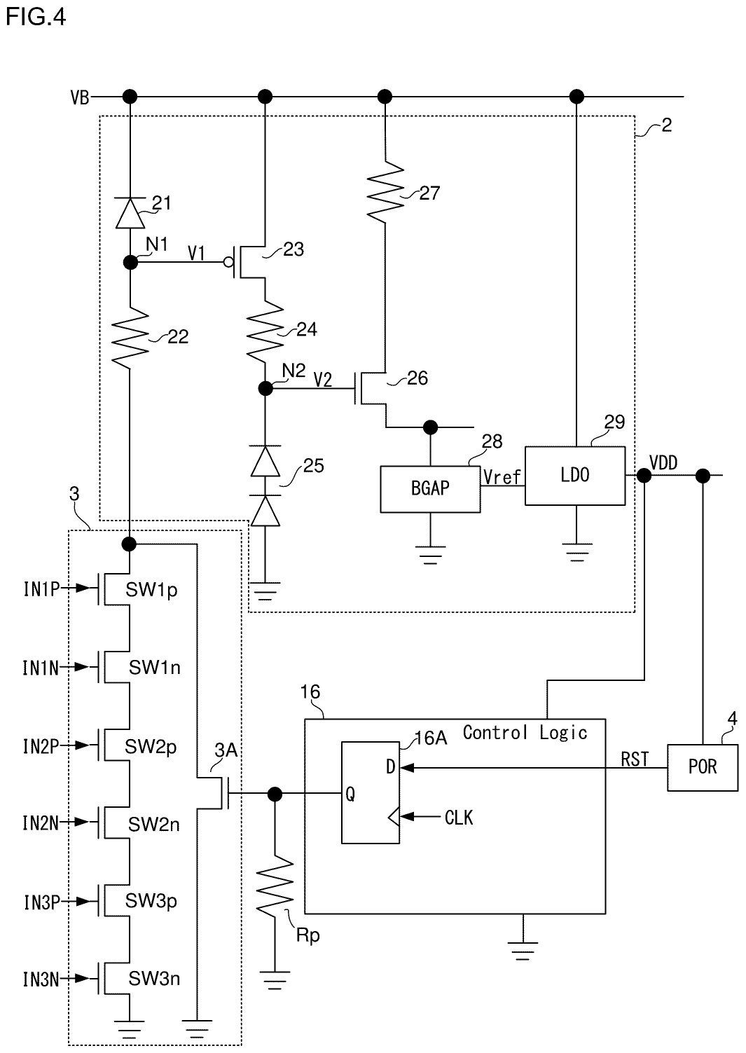

FIG. 4 shows exemplary specific configurations of the reference power supply circuit 2 and the switch circuit 3. The reference power supply circuit 2 includes a Zener diode 21, a resistor 22, a PDMOS transistor (P-channel double-diffused MOSFET) 23, a resistor 24, a Zener diode 25, an NDMOS transistor (N-channel double-diffused MOSFET) 26, a resistor 27, a bandgap reference 28, and an LDO 29.

A cathode of the Zener diode 21 is connected to the application terminal of the power supply voltage VB. An anode of the Zener diode 21 is connected to one end of the resistor 22. The other end of the resistor 22 is connected to the switch circuit 3. The Zener diode 21 and the resistor 22 are connected to a node N1, and the node N1 is connected to a gate of the PDMOS transistor 23. A source of the PDMOS transistor 23 is connected to the application terminal of the power supply voltage VB. A drain of the PDMOS transistor 23 is connected to one end of the resistor 24. The other end of the resistor 24 is connected to a cathode of the Zener diode 25. An anode of the Zener diode 25 is connected to an application terminal of a ground potential. The resistor 24 and the Zener diode 25 are connected to a node N2, and the node N2 is connected to a gate of the NDMOS transistor 26. A drain of the NDMOS transistor 26 is connected to one end of the resistor 27. The other end of the resistor 27 is connected to the application terminal of the power supply voltage VB.

The switch circuit 3 includes a U-phase upper switch SW1p, a U-phase lower switch SW In, a V-phase upper switch SW2p, a V-phase lower switch SW2n, a W-phase upper switch SW3p, and a W-phase lower switch SW3n. Each of these switches is composed of an N-channel MOSFET.

A drain of the U-phase upper switch SW1p is connected to the other end of the resistor 22. A source of the U-phase upper switch SW1p is connected to a drain of the U-phase lower switch SWIn. A source of the U-phase lower switch SWIn is connected to a drain of the V-phase upper switch SW2p. A source of the V-phase upper switch SW2p is connected to a drain of the V-phase lower switch SW2n. A source of the V-phase lower switch SW2n is connected to a drain of the W-phase upper switch SW3p. A source of the W-phase upper switch SW3p is connected to a drain of the W-phase lower switch SW3n. A source of the W-phase lower switch SW3n is connected to an application terminal of a ground potential. Specifically, all the switches SW1p to SW3n are connected in series. The order in which the switches are connected is not limited to the configuration shown in FIG. 4 but may be determined arbitrarily.

The U-phase upper control input signal IN1P is input to a gate of the U-phase upper switch SW1p. The U-phase lower control input signal IN1N is input to a gate of the U-phase lower switch SWIn. The V-phase upper control input signal IN2P is input to a gate of the V-phase upper switch SW2p. The V-phase lower control input signal IN2N is input to a gate of the V-phase lower switch SW2n. The W-phase upper control input signal IN3P is input to a gate of the W-phase upper switch SW3p. The W-phase lower control input signal IN3N is input to a gate of the W-phase lower switch SW3n.

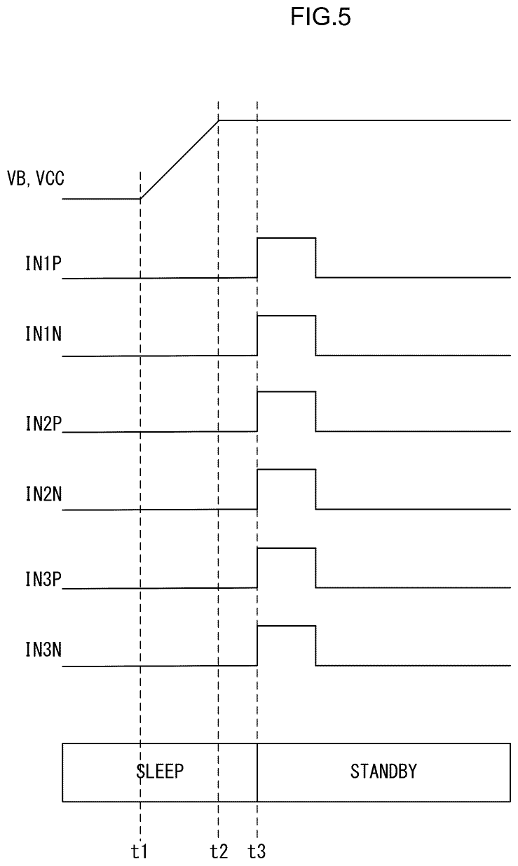

Here, activation of the semiconductor device 1 using the configuration shown in FIG. 4 will be described by referring to the timing chart in FIG. 5. FIG. 5 shows the power supply voltages VB and VCC, the control input signals INIP, ININ, IN2P, IN2N, IN3P, IN3N, and the state of the semiconductor device 1 in this order from the top.

When an ignition of a vehicle mounted with the motor system 5 is turned on, the power supply voltage (battery voltage) VB becomes on. This causes the power supply voltage VB to start to rise from 0 V (timing t1), as shown in FIG. 5. This also causes the power supply voltage VCC as a power supply of the microcontroller 30 to rise.

After timing t2 when the power supply voltages VB and VCC rise to a steady state (high level), the microcontroller 30 switches each of the control input signals INIP, ININ, IN2P, IN2N, IN3P, and IN3N from a low level to a high level (timing t3). This brings each of the switches SW1p to SW3n to an on state, thereby causing a current to start to flow in the Zener diode 21.

A voltage V1 generated at the node N1 is clamped at a voltage lower than the power supply voltage VB by a breakdown voltage of the Zener diode 21. This brings the PDMOS transistor 23 to an on state, thereby causing a current to flow in the Zener diode 25. By doing so, a voltage V2 (a voltage at the node N2) to be applied to the gate of the NDMOS transistor 26 is clamped at a breakdown voltage of the Zener diode 25. Thus, a source voltage at the NDMOS transistor 26 substantially equal to the voltage V2 is applied to the bandgap reference 28. The bandgap reference 28 generates a reference voltage Vref on the basis of the source voltage at the NDMOS transistor 26.

As the reference voltage Vref becomes on, the LDO 29 is activated. The LDO 29 steps down the power supply voltage VB to generate the reference power supply voltage VDD. The generated reference power supply voltage VDD is supplied to the control logic unit 16. By doing so, the semiconductor device 1 makes a transition from a sleep state to a standby state where the control logic unit 16 is operable in response to supply of the reference power supply voltage VDD.

Here, as shown in FIG. 4, the control logic unit 16 includes a flip-flop 16A. The semiconductor device 1 includes a power-on reset unit 4. The flip-flop 16A has a D terminal to which a reset release signal RST output from the power-on reset unit 4 is input. The flip-flop 16A has a clock terminal to which a clock signal CLK is input.

The switch circuit 3 includes a latching switch 3A. The latching switch 3A is composed of an N-channel MOSFET. A drain of the latching switch 3A is connected to the drain of the U-phase upper switch SW1p. A source of the latching switch 3A is connected to an application terminal of a ground potential. Specifically, the latching switch 3A is connected in parallel with a configuration where the switches SW1p to SW3n are connected in series. A Q output terminal of the flip-flop 16A is connected to a gate of the latching switch 3A.

A pull-down resistor Rp is connected to the gate of the latching switch 3A. By doing so, even if the Q output terminal is open while the flip-flop 16A is not activated, it is still possible to fix the gate of the latching switch 3A to a low level using the pull-down resistor Rp. At this time, the latching switch 3A is in an off state.

If the power-on reset unit 4 determines that the reference power supply voltage VDD becomes on as described above, the power-on reset unit 4 outputs the reset release signal RST representing reset release. At this time, the reset release signal RST is at a high level, so that a high-level signal is output from the Q output terminal of the flip-flop 16A. As a result, the latching switch 3A is brought to an on state. Then, independently of the logic level of each of the control input signals INIP to IN3N, a state is latched where a current flows in the Zener diode 21 and the reference power supply voltage VDD is on.

As described above, according to the present embodiment, the reference power supply circuit 2 is activated by using the control input signals INIP to IN3N in common for driving the corresponding transistors in the half bridges UH, VH, and WH of the respective phases, thereby allowing the semiconductor device 1 to be activated. After the semiconductor device 1 is activated, it is possible to latch the activated state independently of the logic level of each of the control input signals INIP to IN3N (during driving of the motor 35, for example).

In particular, according to the present embodiment, the switch circuit 3 is provided with the switches SW1p to SW3n corresponding to all the control input signals INIP to IN3N respectively for driving the three-phase motor 35. By doing so, even if any of the control input signals INIP to IN3N output from the microcontroller 30 becomes unstable during rise of the power supply voltage VCC to be supplied to the microcontroller 30, the reference power supply circuit 2 is not activated unless all the control input signals INIP to IN3N are brought to high levels. Thus, it is possible to reduce a probability that the reference power supply circuit 2 will be activated with unintentional timing. Specifically, it is possible to activate the reference power supply circuit 2 with timing when the control input signals INIP to IN3N are brought to high levels according to a control sequence implemented by the microcontroller 30 (with intentional timing).

### 2.3 Modifications

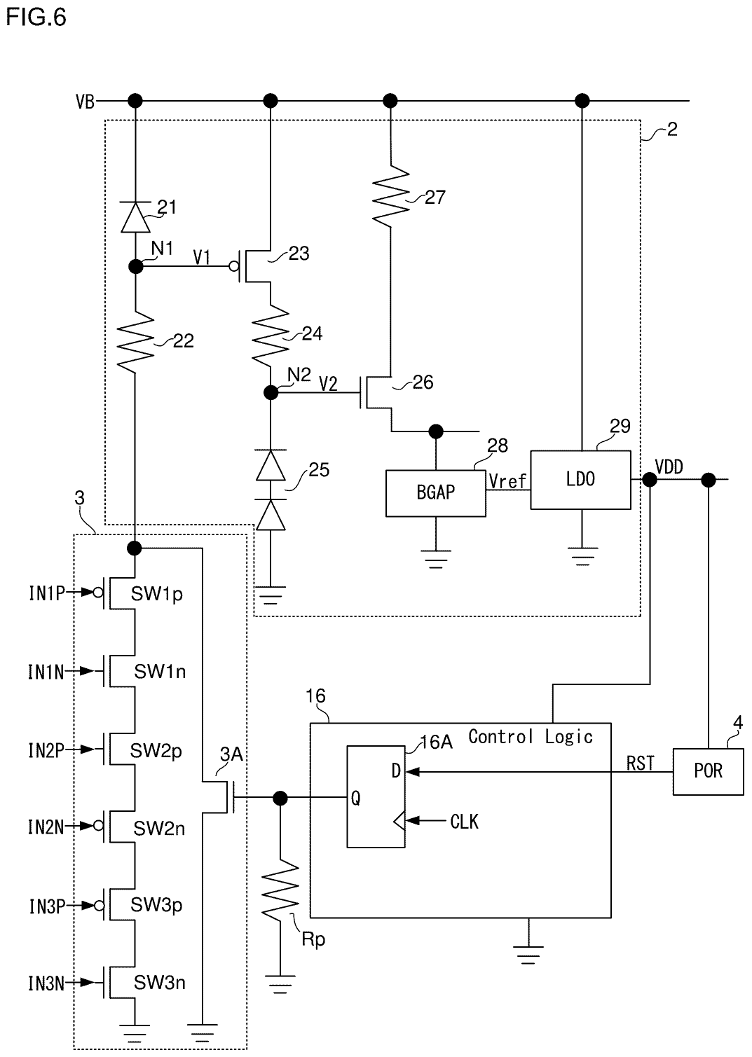

FIG. 6 shows the configuration of a switch circuit 3 according to a modification. Unlike in the configuration described previously (FIG. 4), in the switch circuit 3 shown in FIG. 6, the switches SW1p, SW2n, and SW3p are composed of P-channel MOSFETs instead of N-channel MOSFETs. By doing so, after rises of the power supply voltages VB and VCC, all the switches SW1p to SW3n are brought to an on state to activate the reference power supply circuit 2 when the control input signals are brought to levels as follows by the microcontroller 30: INIP=low level, ININ=high level, IN2P=high level, IN2N=low level, IN3P=low level, and IN3N=high level.

The switch circuit 3 may be configured to activate the reference power supply circuit 2 when a combination of the logic levels of the control input signals is different from that described above.

### 2.4 Application to Vehicle

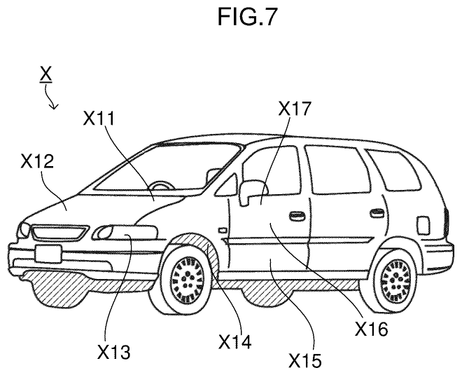

FIG. 7 is an appearance view showing one exemplary configuration of a vehicle mounted with the motor system 5 described previously. In FIG. 7, various types of motors X11 to X17 mounted on a vehicle X are shown as exemplary applications of the motor 35.

X11 is a motor for electric power steering. X12 is a motor for an electric oil pump. X13 is a motor for headlight driving. X14 is a motor for an electric parking brake. X15 is a motor for a sheet cooling fan. X16 is a motor for door opening and closing. X17 is a motor for door locking.

### 3. Others

The various technical features disclosed in the present description can be implemented in any other manner than in the embodiments described above and allow for many modifications within a range not departing from the spirit of the technical creations thereof. Specifically, the above embodiment should be understood to be in every aspect illustrative and not restrictive. The technical scope of the present invention is not limited to the above embodiment but should be understood to encompass every modification belonging to a sense and a scope equivalent to those of the claims.

The semiconductor device is not limited to a configuration as a gate driver for motor driving but may be configured as a gate driver for a DC/DC converter with one-half bridge, for example.

### 4. Appendixes

As described above, a semiconductor device (1) according to one aspect of the present disclosure has a configuration (first configuration), for example, where the semiconductor device makes at least one-half bridge (UH, VH, WH) drivable including an upper transistor (Q1H, Q2H, Q3H) and a lower transistor (Q1L, Q2L, Q3L), and comprises:
an upper control input terminal (T1p, T2p, T3p) configured to allow input of an upper control input signal (IN1P, IN2P, IN3P) for controlling driving of the upper transistor;
a lower control input terminal (Tln, T2n, T3n) configured to allow input of a lower control input signal (IN1N, IN2N, IN3N) for controlling driving of the lower transistor;
a power supply terminal (Tvb) configured to allow input of a power supply voltage (VB);
a control logic unit (16);
a reference power supply circuit (2) configured to receive supply of the power supply voltage and to allow generation of a reference power supply voltage (VDD) to be supplied to the control logic unit; and
a switch circuit (3) including switches (SW1p, SW2p, SW3p, SWIn, SW2n, SW3n) provided for the upper control input signal and the lower control input signal respectively and switched between on and off in response to logic levels of the upper control input signal and the lower control input signal respectively, wherein
the reference power supply circuit is configured to be activated on the basis of a combination of the logic levels of the upper control input signal and the lower control input signal.

The first configuration may have a configuration (a second configuration) where the reference power supply circuit (2) is configured to be activated if each of the upper control input signal (IN1P, IN2P, IN3P) and the lower control input signal (IN1N, IN2N, IN3N) is at a high level.

The second configuration may have a configuration (a third configuration) where all of the switches (SW1p, SW2p, SW3p, SWIn, SW2n, SW3n) are composed of N-channel MOSFETs and are connected in series between the reference power supply circuit (2) and a ground potential.

Any one of the first to third configurations may have a configuration (a fourth configuration) where the reference power supply circuit (2) includes:
a first diode (21) having a cathode connected to an application terminal of the power supply voltage (VB);
a first resistor (22) having a first end connected to an anode of the first diode, and a second end connected to the switch circuit (3);
a PMOS transistor (23) having a gate connected to a first node (N1) to which the first diode and the first resistor are connected, and a source connected to the application terminal of the power supply voltage;
a second resistor (24) having a first end connected to a drain of the PMOS transistor;
a second diode (25) having a cathode connected to a second end of the second resistor, and an anode connected to an application terminal of a ground potential;
an NMOS transistor (26) having a gate connected to a second node (N2) to which the second resistor and the second diode are connected;
a third resistor (27) connected between the application terminal of the power supply voltage and a drain of the NMOS transistor;
a bandgap reference (28) connected to a source of the NMOS transistor; and
an LDO (29) configured to be activated on the basis of a reference voltage (Vref) output from the bandgap reference and to generate the reference power supply voltage (VDD) from the power supply voltage.

Any one of the first to fourth configurations may have a configuration (a fifth configuration) where the semiconductor device further comprises a detection unit (4) configured to detect activation of the reference power supply voltage (VDD), wherein
the switch circuit (3) includes a latching switch (3A) connected in parallel with a configuration where the switches (SW1p, SW2p, SW3p, SW In, SW2n, SW3n) are connected in series, and
the control logic unit (16) is configured to maintain the latching switch in an on state on the basis of detection by the detection unit.

Any one of the first to fifth configurations may have a configuration (a sixth configuration) where the at least one-half bridge includes half bridges (UH, VH, WH) of a U-phase, a V-phase, and a W-phase connected to a three-phase brushless DC motor (35),
the upper control input signal includes a U-phase upper control input signal (INIP), a V-phase upper control input signal (IN2P), and a W-phase upper control input signal (IN3P),
the lower control input signal includes a U-phase lower control input signal (ININ), a V-phase lower control input signal (IN2N), and a W-phase lower control input signal (IN3N), and
the switches include a U-phase upper switch (SW1p) allowing input of the U-phase upper control input signal, a V-phase upper switch (SW2p) allowing input of the V-phase upper control input signal, a W-phase upper switch (SW3p) allowing input of the W-phase upper control input signal, a U-phase lower switch (SWIn) allowing input of the U-phase lower control input signal, a V-phase lower switch (SW2n) allowing input of the V-phase lower control input signal, and a W-phase lower switch (SW3n) allowing input of the W-phase lower control input signal.

The sixth configuration may have a configuration (a seventh configuration) where the U-phase upper switch (SW1p), the V-phase upper switch (SW2p), the W-phase upper switch (SW3p), the U-phase lower switch (SWIn), the V-phase lower switch (SW2n), and the W-phase lower switch (SW3n) are all composed of N-channel MOSFETs and are connected in series between the reference power supply circuit (2) and a ground potential.

A motor system (5) according to one aspect of the present disclosure has a configuration (an eighth configuration) where the motor system comprises: the semiconductor device (1) according to the sixth or seventh configuration; the half bridges (UH, VH, WH) of the U-phase, the V-phase, and the W-phase drivable by the semiconductor device; and the three-phase brushless DC motor (35) connected to the half bridges of the U-phase, the V-phase, and the W-phase.

A vehicle (X) according to one aspect of the present disclosure comprises the motor system according to the eighth configuration.

### INDUSTRIAL APPLICABILITY

The present disclosure is applicable to a motor system to be mounted on a vehicle, for example.

### EXPLANATION OF REFERENCE SIGNS

1 Semiconductor device
2 Reference power supply circuit
3 Switch circuit
3A Latching switch
4 Power-on reset unit
5 Motor system
10 Semiconductor device
11 Regulator
12 Reference power supply circuit
13 Schmitt buffer
14A to 14E Schmitt buffer
15 Charge pump
16 Control logic unit
16A Flip-flop
17H, 17L Pre-driver
18H, 18L Pre-driver
19H, 19L Pre-driver
21 Zener diode
22 Resistor
23 PDMOS transistor
24 Resistor
25 Zener diode
26 NDMOS transistor
27 Resistor
28 Bandgap reference
30 Microcontroller
35 Motor
50 Motor system
C1H, C1L, C2H, C2L, C3H, C3L Capacitor
Q1H U-phase upper transistor
Q1L U-phase lower transistor
Q2H V-phase upper transistor
Q2L V-phase lower transistor
Q3H W-phase upper transistor
Q3L W-phase lower transistor
R1H Pull-down resistor
R1L Pull-down resistor
R2H Pull-down resistor
R2L Pull-down resistor
R3H Pull-down resistor
R3L Pull-down resistor
Rp Pull-down resistor
SWIn U-phase lower switch
SW1p U-phase upper switch
SW2n V-phase lower switch
SW2p V-phase upper switch
SW3n W-phase lower switch
SW3p W-phase upper switch
UH U-phase half bridge
VH V-phase half bridge
WH W-phase half bridge
X Vehicle

What is claimed is:

1. A semiconductor device that makes at least one-half bridge drivable including an upper transistor and a lower transistor, the semiconductor device comprising:
an upper control input terminal configured to allow input of an upper control input signal for controlling driving of the upper transistor;
a lower control input terminal configured to allow input of a lower control input signal for controlling driving of the lower transistor;
a power supply terminal configured to allow input of a power supply voltage;
a control logic unit;
a reference power supply circuit configured to receive supply of the power supply voltage and to allow generation of a reference power supply voltage to be supplied to the control logic unit; and
a switch circuit including switches provided for the upper control input signal and the lower control input signal respectively and switched between on and off in response to logic levels of the upper control input signal and the lower control input signal respectively, wherein
the reference power supply circuit is configured to be activated on the basis of a combination of the logic levels of the upper control input signal and the lower control input signal.

2. The semiconductor device according to claim 1, wherein
the reference power supply circuit is configured to be activated if each of the upper control input signal and the lower control input signal is at a high level.

3. The semiconductor device according to claim 2, wherein
all of the switches are composed of N-channel MOSFETs and are connected in series between the reference power supply circuit and a ground potential.

4. The semiconductor device according to claim 1, wherein
the reference power supply circuit includes:
a first diode having a cathode connected to an application terminal of the power supply voltage;
a first resistor having a first end connected to an anode of the first diode, and a second end connected to the switch circuit;
a PMOS transistor having a gate connected to a first node to which the first diode and the first resistor are connected, and a source connected to the application terminal of the power supply voltage;
a second resistor having a first end connected to a drain of the PMOS transistor;
a second diode having a cathode connected to a second end of the second resistor, and an anode connected to an application terminal of a ground potential;
an NMOS transistor having a gate connected to a second node to which the second resistor and the second diode are connected;
a third resistor connected between the application terminal of the power supply voltage and a drain of the NMOS transistor;
a bandgap reference connected to a source of the NMOS transistor; and
an LDO configured to be activated on the basis of a reference voltage output from the bandgap reference and to generate the reference power supply voltage from the power supply voltage.

5. The semiconductor device according to claim 1, further comprising:
a detection unit configured to detect activation of the reference power supply voltage, wherein
the switch circuit includes a latching switch connected in parallel with a configuration where the switches are connected in series, and
the control logic unit is configured to maintain the latching switch in an on state on the basis of detection by the detection unit.

6. The semiconductor device according to claim 1, wherein
the at least one-half bridge includes half bridges of a U-phase, a V-phase, and a W-phase connected to a three-phase brushless DC motor,
the upper control input signal includes a U-phase upper control input signal, a V-phase upper control input signal, and a W-phase upper control input signal,
the lower control input signal includes a U-phase lower control input signal, a V-phase lower control input signal, and a W-phase lower control input signal, and
the switches include a U-phase upper switch allowing input of the U-phase upper control input signal, a V-phase upper switch allowing input of the V-phase upper control input signal, a W-phase upper switch allowing input of the W-phase upper control input signal, a U-phase lower switch allowing input of the U-phase lower control input signal, a V-phase lower switch allowing input of the V-phase lower control input signal, and a W-phase lower switch allowing input of the W-phase lower control input signal.

7. The semiconductor device according to claim 6, wherein
the U-phase upper switch, the V-phase upper switch, the W-phase upper switch, the U-phase lower switch, the V-phase lower switch, and the W-phase lower switch are all composed of N-channel MOSFETs and are connected in series between the reference power supply circuit and a ground potential.

8. A motor system comprising:
the semiconductor device according to claim 6,
the half bridges of the U-phase, the V-phase, and the W-phase drivable by the semiconductor device; and
the three-phase brushless DC motor connected to the half bridges of the U-phase, the V-phase, and the W-phase.

9. A vehicle comprising the motor system according to claim 8.
